(19) United States
(12) Patent Application Publication
(10) Pub. No.: US 2015/0021070 A1
(43) Pub. Date: Jan. 22, 2015

(54) WIRING BOARD AND METHOD FOR MANUFACTURING WIRING BOARD

(71) Applicant: IBIDEN CO., LTD., Ogaki-shi (JP)

(72) Inventors: Takenobu NAKAMURA, Ogaki-shi (JP); Yoshiaki Mori, Ogaki-shi (JP); Yu Sasaki, Ogaki-shi (JP)

(73) Assignee: IBIDEN CO., LTD., Ogaki-shi (JP)

(21) Appl. No.: 14/333,825

(22) Filed: Jul. 17, 2014

(30) Foreign Application Priority Data
Jul. 19, 2013 (JP) 2013-150919

(51) Int. Cl. H05K 3/10; H05K 1/09

(52) U.S. Cl. CPC H05K 3/10; H05K 1/092
USPC 174/257; 174/250; 29/846

(57) ABSTRACT

A wiring board includes an insulation layer, and a conductive pattern formed on the insulation layer having a repaired disconnected portion. The repaired disconnected portion has a first conductive layer connecting disconnected edges of the conductive pattern and a second conductive layer covering the first conductive layer, the first conductive layer has a first electrical resistivity which is set higher than an electrical resistivity of the conductive pattern, and the second conductive layer has a second electrical resistivity which is set lower than the first electrical resistivity of the first conductive layer.

### CROSS-REFERENCE TO RELATED APPLICATIONS

The present application is based upon and claims the benefit of priority to Japanese Patent Application No. 2013-150919, filed Jul. 19, 2013, the entire contents of which are incorporated herein by reference.

### BACKGROUND OF THE INVENTION

1. Field of the Invention

The present invention relates to a wiring board and its manufacturing method, more specifically, to repairing a disconnected portion of a conductive pattern in a wiring board.

2. Description of Background Art

JP 2000-151081A describes a technology for repairing a disconnected portion of a conductive pattern in a wiring board. Referring to FIG. 12, a wiring board 101 has a disconnection of conductive pattern 103 on insulation layer 102. The portion between both edges (106a, 106b) of disconnected portion 106 of conductive pattern 103 is connected by conductive paste 111. Conductive paste 111 contains silver powder, which is a conductive substance, and a binder made of a synthetic resin. The entire contents of this publication are incorporated herein by reference.

### SUMMARY OF THE INVENTION

According to one aspect of the present invention, a wiring board includes an insulation layer, and a conductive pattern formed on the insulation layer having a repaired disconnected portion. The repaired disconnected portion has a first conductive layer connecting disconnected edges of the conductive pattern and a second conductive layer covering the first conductive layer, the first conductive layer has a first electrical resistivity which is set higher than an electrical resistivity of the conductive pattern, and the second conductive layer has a second electrical resistivity which is set lower than the first electrical resistivity of the first conductive layer.

According to another aspect of the present invention, a method for manufacturing a wiring board includes applying a conductive paste including metal particles to a disconnected portion of a conductive pattern such that a layer of the conductive paste is formed between disconnected edges of the disconnected portion of the conductive pattern, drying the layer of the conductive paste formed between the disconnected edges of the disconnected portion such that a conductive-paste layer having a first electrical resistivity which is set higher than an electrical resistivity of the conductive pattern is formed between the disconnected edges of the disconnected portion, and electrolytically plating the conductive-paste layer using the conductive-paste layer as a power-supply layer such that a plated layer having a second electrical resistivity which is set lower than the first electrical resistivity of the conductive-paste layer is formed to cover the conductive paste layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board according to an embodiment;

FIG. 2 is a plan view illustrating a step for repairing the disconnected portion of a conductive pattern, and showing a disconnected wiring board that includes a disconnected conductive pattern;

FIG. 3 is an enlarged view of portion “A” in FIG. 2, showing the vicinity of a disconnected portion;

FIG. 4 is a plan view of a repair step subsequent to FIG. 3, showing the disconnected wiring board on which the resist is formed;

FIG. 5 is a plan view of a repair step subsequent to FIG. 4, showing a plan view where a conductive paste has been applied on the disconnected portion;

FIG. 6 is a cross-sectional view at “VI-VI” in FIG. 5, showing a conductive paste being applied on the disconnected portion;

FIG. 7 is a cross-sectional view of a repair step subsequent to FIG. 6, showing the conductive paste being dried;

FIG. 8 is a plan view of a repair step subsequent to FIG. 7, showing a state where excess portions of the dried conductive paste have been removed;

FIG. 9 is a plan view of a repair step subsequent to FIG. 8, showing a state where the resist has been removed from the wiring board;

FIG. 10 is a view of a repair step subsequent to FIG. 9, showing metal plating being performed on the conductive-paste layer;

FIG. 11 is an enlarged view of portion “B” in FIG. 10, showing the boundary portion between the conductive-paste layer and the plated layer; and

FIG. 12 is a cross-sectional view of a wiring board according to conventional art.

### DETAILED DESCRIPTION OF THE EMBODIMENTS

The embodiments will now be described with reference to the accompanying drawings, wherein like reference numerals designate corresponding or identical elements throughout the various drawings.

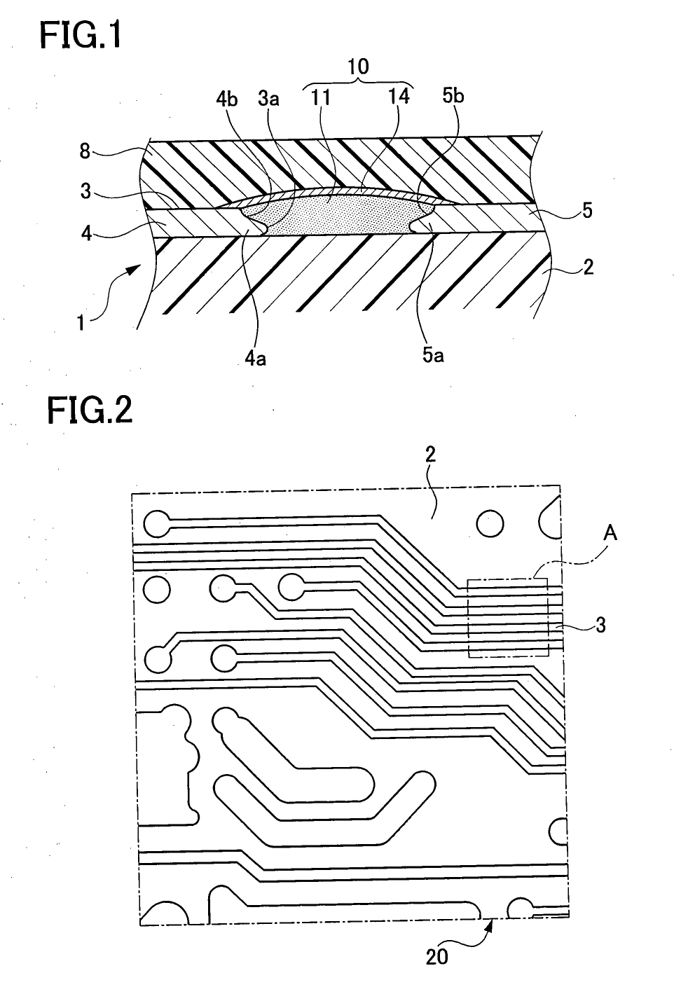

In the following, embodiments of the present invention are described in detail with reference to the accompanying drawings. FIG. 1 is a cross-sectional view showing wiring board 1 according to the present embodiment. As shown in FIG. 1, wiring board 1 of the present embodiment has insulation layer 2.

Conductive pattern (wiring pattern) 3 is formed on one main surface (2a) of insulation layer 2 (upper surface: the surface on the upper side in FIG. 1). Conductive pattern 3 is made of a copper foil. Conductive pattern 3 may be formed with copper plating, or may be made up of a copper foil and copper plating.

In conductive pattern 3, there is a repaired disconnected portion (3a) where the disconnected wiring is repaired. Conductive-paste layer 11 (corresponds to a first conductive layer) and plated layer 14 (corresponds to a second conductive layer) are provided for repaired disconnected portion (3a). More specifically, because of a disconnection, a portion of conductive pattern 3 is missing between first pattern portion 4 positioned on the left side of FIG. 1 and second pattern portion 5. Disconnection edge (4a) of first pattern portion 4 (one edge of repaired disconnected portion (3a)) and disconnection edge (5a) of second pattern portion 5 (the other edge of repaired disconnected portion (3a)) are connected by conductive-paste layer 11. Conductive-paste layer 11 is formed by applying a conductive paste containing metal (silver, in the present embodiment) powder and a binder made of a synthetic resin, and then by drying the paste.

Plated layer 14 made of copper plating is formed on conductive-paste layer 11. Copper plating may be copper electroplating or copper electroless plating. Plated layer 14 covers conductive-paste layer 11. In addition, plated layer 14 also extends to the upper surface of disconnection edge (4a) of first pattern portion 4 and to the upper surface of disconnection edge (5a) of second pattern portion 5. Plated layer 14 directly covers those edge portions without having conductive-paste layer 11 sandwiched in between. Conductive-paste layer 11 and plated layer 14 form repaired disconnected portion 10 obtained by repairing a disconnection.

On conductive pattern 3, insulation layer 8 as its upper layer (upper insulation layer) is further laminated. Upper insulation layer 8 is in contact with plated layer 14.

Following is a description of the process for repairing a disconnection of conductive pattern 3 in wiring board 1 of the present embodiment. The process for repairing a disconnection includes the steps 1˜5 below:

1. Forming resist 30;

2. Applying conductive paste 40;

3. Drying conductive paste 40 and removing a portion;

4. Removing resist 30; and

5. Forming plated layer 14.

### Forming Resist

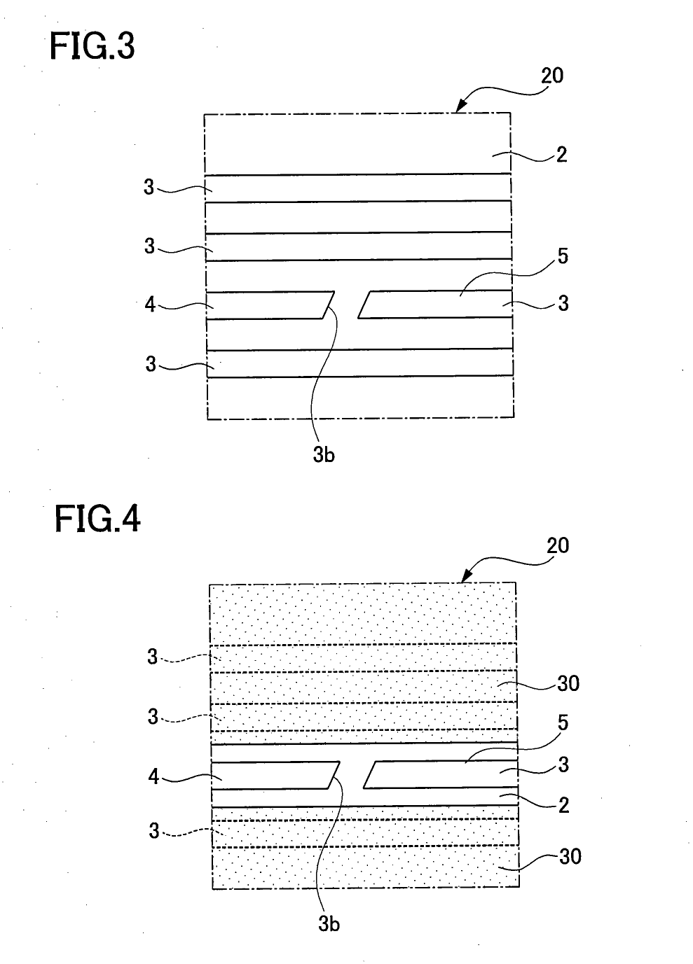

FIG. 2 is a plan view showing a wiring board where conductive pattern 3 is formed on insulation layer 2. FIG. 3 is an enlarged view of portion “A” in FIG. 2. As shown in FIG. 3, there is a disconnected portion (3b) in conductive pattern 3. Namely, a portion between first pattern portion 4 and second pattern portion 5 is missing from conductive pattern 3, resulting in no conduction between them. A wiring board with disconnected portion (3b) is referred to as “disconnected wiring board 20” in the following. Here, edge surface (disconnected edge surface) (4b) formed by disconnection at first pattern portion 4 and edge surface (disconnected edge surface) (5b) formed by disconnection at first pattern portion 5 are each a slope opening wider upward as shown in FIG. 1. What is indicated by the aforementioned disconnection edge (4a) is not only disconnection edge surface (4b) itself, but also the portion having a certain length that includes disconnection edge surface (4b). Also, what is indicated by disconnection edge (5a) is not only disconnection edge surface (5b) itself, but also the portion having a certain length that includes disconnection edge surface (5b). In addition, the present embodiment describes disconnected portion (3b) as positioned in portion “A” in FIG. 2, but the position is not limited specifically.

In the process for repairing disconnected portion (3b), first, resist 30 is formed on disconnected wiring board 20 as shown in FIG. 4. Resist 30 is formed in such a way as not to cover disconnected portion (3b), first pattern portion 4, second pattern portion 5 or part of insulation layer 2 adjacent to those portions, but to cover the rest of wiring board 20. A known method is used for forming resist 30. In the present embodiment, resist 30 is formed by coating resist film on disconnected wiring board 20. Resist film is coated while avoiding disconnected portion (3b), first pattern portion 4, second pattern portion 5 and part of insulation layer 2 adjacent to those portions. Resist 30 is formed to prevent conductive paste 40 from attaching to portions other than the desired portion when the conductive paste is applied on disconnected wiring board 20 in a later repair step.

### Applying Conductive Paste

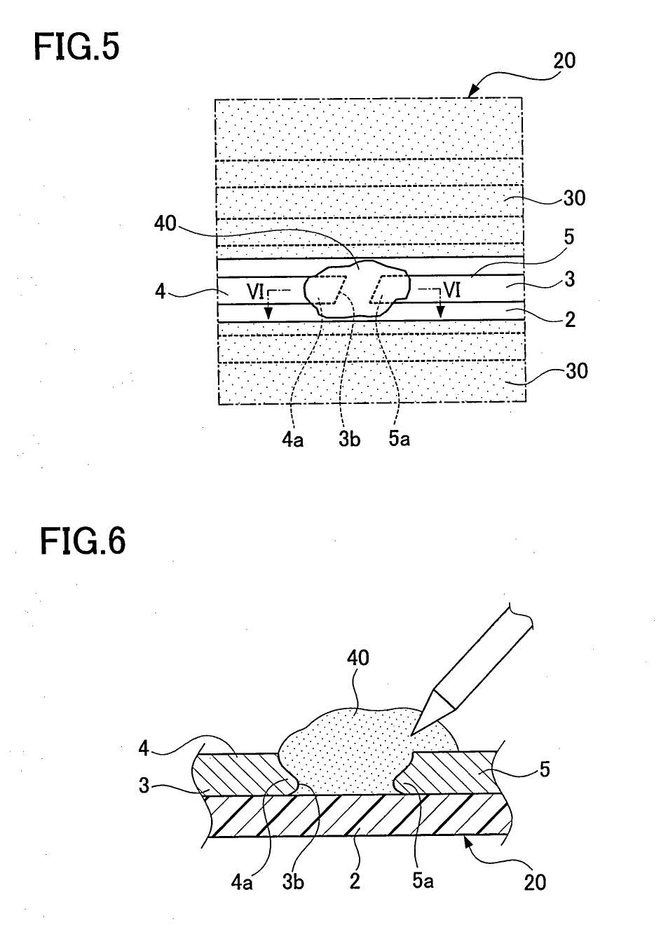

Next, as shown in FIGS. 5 and 6, conductive paste 40 is applied on disconnected portion (3b) of conductive pattern 3. Namely, conductive paste 40 is applied on disconnection edge (4a) of first pattern portion 4, disconnection edge (5a) of second pattern portion 5, and insulation layer 2 between both edges so as to connect first pattern portion 4 and second pattern portion 5 of conductive pattern 3. Conductive paste 40 is obtained by combining into a solvent a powder component containing at least silver powder and a binder made of a thermosetting resin.

### Drying Conductive Paste and Removing a Portion

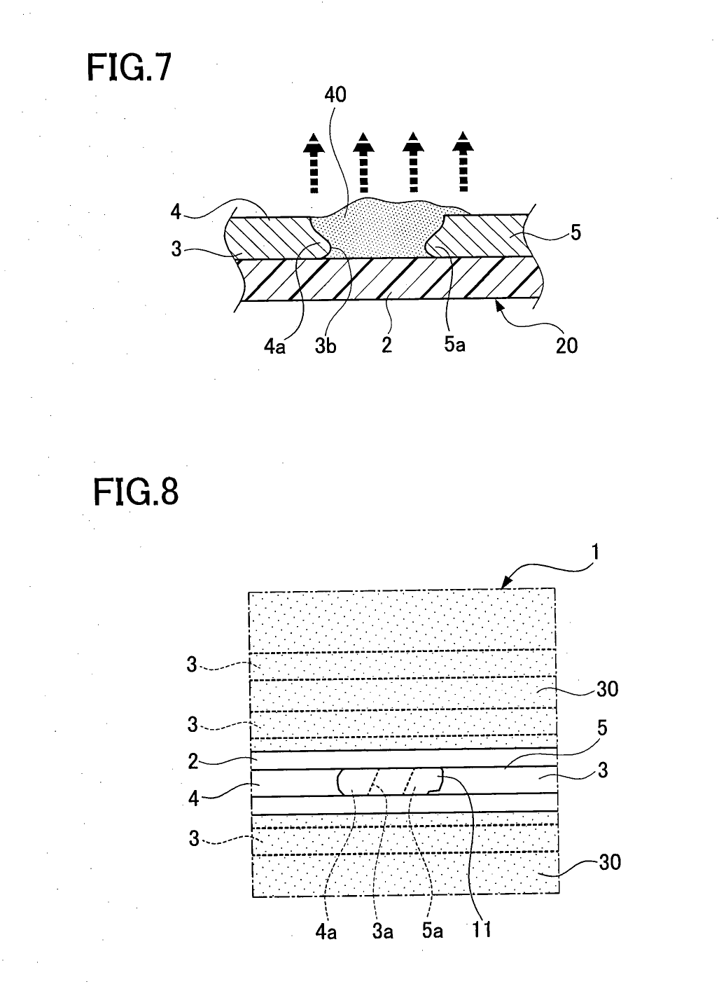

Next, disconnected wiring board 20 with applied conductive paste 40 is placed into an oven and heated so as to dry conductive paste 40 as shown in FIG. 7. Accordingly, the solvent in conductive paste 40 is removed through evaporation and the binder is cured. As a result, conductive paste 40 contracts slightly.

After that, excess portions of dried conductive paste 40 are removed to shape conductive paste 40. Namely, excess portions of conductive paste 40 are removed so that the width of dried conductive paste 40 corresponds to the width of conductive pattern 3, and the thickness of dried conductive paste 40 becomes as close as possible to the thickness of conductive pattern 3. The reason to make the thickness of dried conductive paste 40 closer to the thickness of conductive pattern 3 is so that it does not affect the flatness of the upper layers such as upper insulation layer 8 to be formed on conductive pattern 3 in a subsequent process. Excess portions of conductive paste 40 are removed, for example, by filing. Accordingly, conductive-paste layer 11 with the shape shown in FIG. 8 is formed. Hereinafter, the substrate shown in FIG. 8 where first pattern portion 4 and second pattern portion 5 are connected for electrical conduction is referred to as wiring board 1. Also, disconnected portion (3b) in disconnected wiring board 20 is referred to as repaired disconnected portion (3a) in wiring board 1.

### Removing Resist

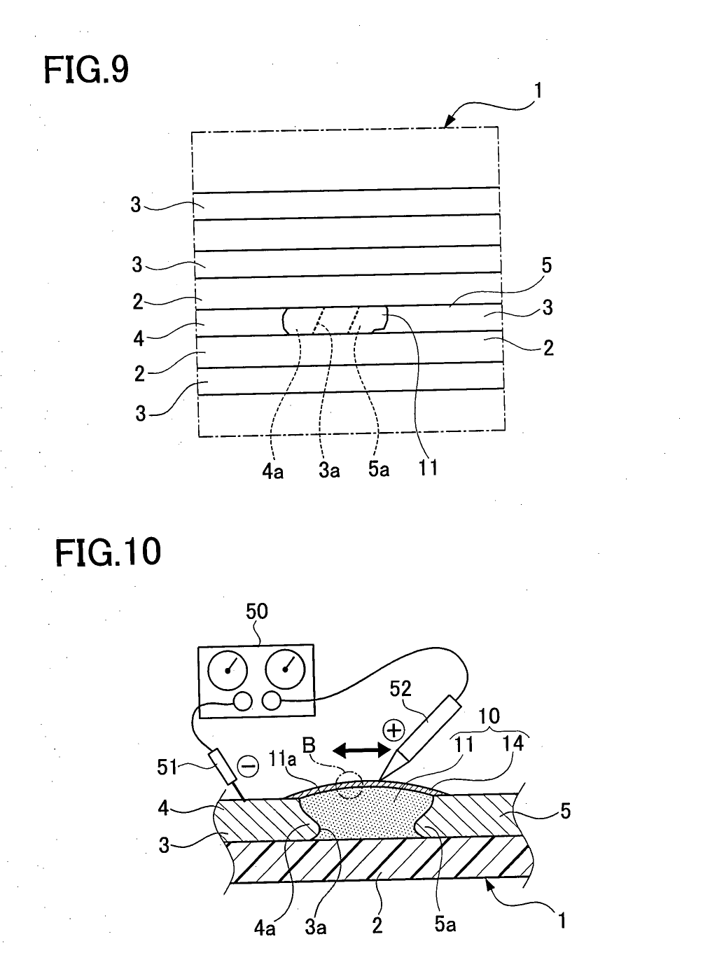

Next, as shown in FIG. 9, resist 30 is removed. Namely, the resist film is removed. Removal of resist film may be conducted by a known method, for example, by peeling, burning or dissolving the film. By doing so, conductive pattern 3 covered by the resist film is exposed.

### Forming Plated Layer

Next, as shown in FIG. 10, by using a commercially available brush plating device 50, copper electroplating is performed on a portion so as to form plated layer 14 mainly on conductive-paste layer 11. More specifically, negative electrode 51 of plating device 50 makes contact with conductive pattern 3, a plating solution containing copper sulfate, for example, is held in brush 52 as a positive electrode, and brush 52 is moved so as to apply the plating solution on the portion where plating is to be applied. In addition to conductive-paste layer 11, other portions where plating is to be applied include those on disconnected edge (4a) of first pattern portion 4 and on disconnected edge (5a) of second pattern portion 5. Accordingly, plated layer 14 is formed to cover upper surfaces of conductive-paste layer 11, disconnected edge (4a) of first pattern portion 4 and disconnected edge (5a) of second pattern portion 5. In the copper electroplating, conductive-paste layer 11 works as a power-supply layer (base layer).

The thickness of plated layer 14 to be formed is preferred to be 0.1 μm or greater but 20 μm or less. That is because if the thickness of plated layer 14 is less than 0.1 μm, electrical resistance of plated layer 14 is too great and may block electric current from flowing well in plated layer 14. Besides, to form plated layer 14 with a thickness of 20 μm or greater, the time needed to form plated layer 14 will increase.

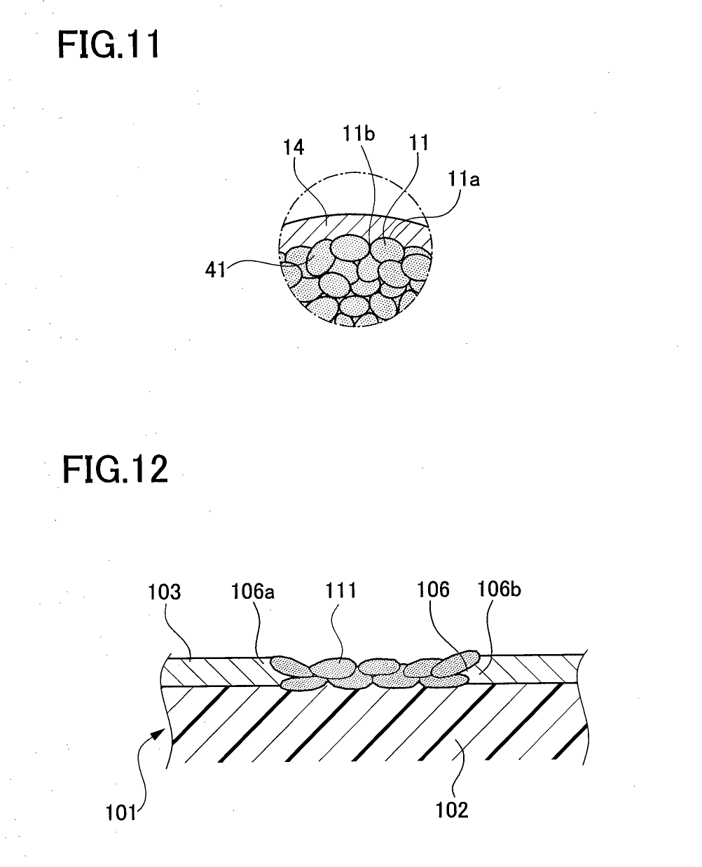

In addition, the surface of conductive-paste layer 11 (the top middle surface in FIG. 10) is concavo-convex surface (11a) (roughened surface), where silver particles 41 are agglomerated as shown in FIG. 11. Plated layer 14 is filled in concavities (11b) of roughened surface (11a) without leaving any space. Namely, plated layer 14 is adhered to the surface of conductive-paste layer 11 without leaving any space.

As described above, repaired disconnected portion 10 made of conductive-paste layer 11 and plated layer 14 is formed. Accordingly, repairing the disconnection of conductive pattern 3 is completed. After that, an upper layer such as upper insulation layer 8 (see FIG. 1) or the like is formed if needed, and insulation at each portion is checked by testing electrical properties and wiring board 1 shown in FIG. 1 is completed as a finished product.

Here, unlike conductive-paste layer 11, plated layer 14 does not contain synthetic resin. Thus, the electrical resistivity of plated layer 14 is lower than that of conductive-paste layer 11. Therefore, compared with a disconnected portion (3b) that is repaired using only conductive-paste layer 11, electrical resistance is lower at repaired disconnected portion (3a) when disconnected portion (3b) is repaired by forming plated layer 14 on conductive-paste layer 11.

The results of testing to confirm the effects of the present embodiment are shown in Table 1 below. As shown in Table 1, electrical resistance at the repaired disconnected portion was 1.50Ω when a disconnected portion (3b) was repaired using only conductive-paste layer 11. On the other hand, electrical resistance at repaired disconnected portion (3a) was 1.28Ω when a disconnected portion (3b) was repaired by forming plated layer 14 on conductive-paste layer 11. Here, electrical resistance at a portion not disconnected at all was 1.19Ω. Therefore, the increase in resistance value was 26% when only conductive-paste layer 11 was used for the repair, whereas the increase in resistance value was 7% when plated layer 14 was also formed for the repair. As described, even if the disconnected portion (3b) is repaired in conductive pattern 3, the electrical resistance at repaired disconnected portion (3a) is kept low according to the present embodiment.

TABLE 1

| | | conductive- | conductive- |
|---|---|---|---|
| | no | paste | paste layer + |
| | disconnection | layer only | plated layer |
| electrical resistance (Ω) | 1.19 | 1.50 | 1.28 |
| increase in resistance (%) | — | 26 | 7 |

As described in detail above, repaired disconnected portion (3a) of wiring board 1 according to the present embodiment is formed with conductive-paste layer 11 as a first conductive layer and plated layer 14 as a second conductive layer. Conductive-paste layer 11 has a first electrical resistivity which is higher than that of conductive pattern 3, and plated layer 14 has a second electrical resistivity which is lower than the first electrical resistivity. Therefore, compared with when a disconnection of conductive pattern 3 is repaired using only conductive-paste layer 11, the electrical resistance at repaired disconnected portion (3a) is kept low.

In addition, in wiring board 1 of the present embodiment, plated layer 14 is formed on conductive-paste layer 11. Thus, compared with when a disconnected portion (3b) is repaired only by plating to have substantially the same thickness as that of conductive pattern 3, the amount of plating is smaller, and the time needed for plating thereby decreases. Accordingly, the time needed to repair the disconnected portion (3b) is shortened, and the manufacturing efficiency of wiring board 1 is enhanced.

In addition, plating layer 14 in wiring board 1 of the present embodiment is filled into concavities (11b) of the concavo-convex surface of conductive-paste layer 11 without leaving any space. Namely, copper plating is impregnated among particles of the powder component that forms the surface of conductive-paste layer 11. Accordingly, adhesiveness of plated layer 14 to conductive-paste layer 11 is high, and plated layer 14 is less likely to peel off from conductive-paste layer 11.

Also, in wiring board 1 of the present embodiment, plated layer 14 directly covers both edges of repaired disconnected portion (3a) (disconnection edges (4a, 5a)) without conductive-paste layer 11 disposed in between, enabling both edges of repaired disconnected portion (3a) of conductive pattern 3 to be conductive through plated layer 14. Therefore, compared with the structure where both edges of repaired disconnected portion (3a) of conductive pattern 3 are not directly covered by plated layer 14, the electrical resistance at repaired disconnected portion (3a) is further lowered.

In addition, conductive pattern 3 and plated layer 14 in wiring board 1 of the present embodiment are made of copper. Therefore, disconnected portion (3b) is repaired to have excellent electrical resistivity.

The embodiments above are simply to show examples of the present invention and do not limit the present invention. Therefore, needless to say, various improvements and modifications are possible within a scope that does not deviate from the gist of the present invention. For example, in the embodiment above, plated layer 14 made of copper plating is formed as a second conductive layer. However, as long as the electrical resistivity of a second conductive layer is lower than that of a first conductive layer, the second conductive layer may be formed using any metal other than copper. Alternatively, methods other than plating may be employed. In addition, conductive-paste layer 11 is formed as a first conductive layer by applying a conductive paste containing silver powder and by drying the paste. However, the first conductive layer may be formed by applying a conductive paste containing powder of a metal other than silver and by drying the paste. Moreover, it is not limited to a layer made by drying a paste. Also, any known plating method other than brush plating may be employed as a method for forming plated layer 14.

Furthermore, in the embodiment above, a completely disconnected portion of conductive pattern 3 is described as disconnected portion (3b). However, a portion which is almost disconnected (such as a portion where the width of conductive pattern 3 is narrowed) may also be considered a disconnected portion. Namely, according to the above embodiment of the present invention, a portion which is almost disconnected in conductive pattern 3 is also repaired.

Moreover, plated layer 14 is formed after resist 30 is removed in the embodiment above. By contrast, plated layer 14 is formed while resist 30 is still present, and then resist 30 may be removed later. By so doing, the plating solution is prevented from attaching to portions other than the desired portion.

When a disconnected portion (3b) does not exist in conductive pattern 3 laminated on insulation layer 2, upper insulation layer 8 is formed without forming conductive-paste layer 11 and plated layer 14.

When a binder contained in a conductive paste is an insulative material, the electrical resistance at a repaired disconnected portion obtained by repairing a disconnection becomes higher than the electrical resistance of the conductive pattern. Therefore, the electrical resistance of a wiring board that includes the repaired disconnected portion becomes higher than the electrical resistance of a wiring board without any repaired disconnected portion.

A wiring board according to an embodiment of the present invention and a manufacturing method according to an embodiment of the present invention keep the electrical resistance at the repaired disconnected portion of a conductive pattern low.

A wiring board according to an embodiment of the present invention is formed by laminating an insulation layer and a conductive pattern. A repaired disconnected portion obtained by repairing a disconnection is included in a conductive pattern. The repaired disconnected portion is characterized by a first conductive layer which connects a portion between the edges of the repaired disconnected portion and has a first electrical resistivity higher than the electrical resistivity of the conductive pattern, and a second conductive layer which covers the first conductive layer and has a second electrical resistivity lower than the first electrical resistivity.

According to the wiring board structured as above, since a second conductive layer with electrical resistivity lower than that of a first conductive layer is provided in the repaired disconnected portion of a conductive pattern, the electrical resistance at the repaired disconnected portion of a conductive pattern is made lower than the resistance when a disconnection of a conductive pattern is repaired using only the first conductive layer.

In the wiring board structured as above, the first conductive layer is preferred to be a conductive-paste layer formed by drying and hardening a conductive paste containing metal particles, and the second conductive layer is preferred to be a plated layer made of metal plating.

By structuring the wiring board as above, since a plated layer with electrical resistivity lower than that of the conductive-paste layer is provided in the repaired disconnected portion of a conductive pattern, the electrical resistance at the repaired disconnected portion of the conductive pattern is made lower than when a disconnection of a conductive pattern is repaired only by a conductive-paste layer. Also, according to the wiring board structured as above, since a plated layer is formed on a conductive-paste layer, the time needed for plating is shorter than when a disconnection of a conductive pattern is repaired only by a plated layer. Accordingly, the time needed for repairing a disconnection in a conductive pattern is shortened, thereby enhancing productivity of a wiring board.

In addition, in the wiring board structured as above, the conductive-paste layer is preferred to have a roughened surface caused by agglomeration of metal particles, and the plated layer is preferred to be filled into the concavities of the roughened surface without leaving any space. By so setting, the adhesiveness of the plated layer and the conductive-paste layer is enhanced, and the plated layer is less likely to peel off from the conductive-paste layer.

Also, in the wiring board structured as above, after the disconnected portion has been connected by the first conductive layer, the second conductive layer is preferred to directly cover both edges of the repaired disconnected portion of a conductive pattern without sandwiching the first conductive layer in between. By so structuring, both edges of the repaired disconnected portion of a conductive pattern are set to be conductive through the second conductive layer. Thus, compared with a structure where a second conductive layer does not directly cover both edges of the repaired disconnected portion of a conductive pattern, electrical resistance at the repaired disconnected portion is further lowered.

Also, in the wiring board structured as above, the conductive patterns and the second conductive layer are preferred to be made of copper. If so, a disconnection of a conductive pattern made of copper is repaired by a second conductive layer made of copper, enabling the repaired disconnected portion to have excellent electrical resistivity.

In the wiring board structured as above, the second conductive layer is preferred to have a thickness of 0.1 μm or greater but 20 μm or less. If the thickness of the second conductive layer is 0.1 μm or greater, the electrical resistance at the second conductive layer will not rise too high, and electrical current flows well in the second conductive layer. In addition, if the thickness of the second conductive layer is 20 μm or less, it does not take much time to form the second conductive layer.

In addition, a method for manufacturing a wiring board according to another embodiment of the present invention is for manufacturing a wiring board by laminating an insulation layer and a conductive pattern. When a disconnection occurs in a conductive pattern laminated on an insulation layer, the method is characterized by taking the following steps prior to laminating an upper insulation layer on the conductive pattern: by applying a conductive paste containing metal particles on the disconnected portion of a conductive pattern and by hardening the paste, a step for forming a paste layer so that a conductive-paste layer is formed to connect both edges of the disconnected portion while having a first electrical resistivity higher than the electrical resistivity of the conductive pattern; and by performing electroplating using the conductive paste as a power-supply layer, a step for forming a plated layer so that a plated layer is formed to cover the conductive-paste layer while having a second electrical resistivity lower than the first electrical resistivity.

According to the method for manufacturing a wiring board, a plated layer is formed on the conductive-paste layer by performing electroplating using the conductive-paste layer as a power-supply layer. Thus, the time needed for plating is made shorter than the plating time when a disconnection of a conductive pattern is repaired only by a plated layer. Accordingly, the time needed to repair the disconnection of a conductive pattern decreases, and the productivity of the wiring board is thereby enhanced.

Here, in the step for forming a paste layer in the above method for manufacturing a wiring board, a conductive-paste layer is preferred to have a roughened surface caused by agglomeration of metal particles; and in the step for forming a plated layer, a plated layer is preferred to be formed while being filled into the concavities of the roughened surface without leaving any space.

Moreover, in the step for forming a plated layer in the above method for manufacturing a wiring board, the plated layer is preferred to directly cover both edges of the disconnected portion of a conductive pattern without having the conductive-paste layer sandwiched in between.

In the above method for manufacturing a wiring board, the conductive pattern is preferred to be made of copper, and in the step for forming a plated layer, the plated layer is preferred to be formed by copper electroplating.

Furthermore, in the step for forming a plated layer in the above method for manufacturing a wiring board, a plated layer is preferred to be formed with a thickness of 0.1 μm or greater but 20 μm or less.

A wiring board according to an embodiment of the present invention and a manufacturing method according to an embodiment of the present invention are capable of exhibiting electrical resistance that is kept low at the repaired disconnected portion of a conductive pattern. Disconnection may occur in a portion of a conductive pattern in a wiring board during the manufacturing process of the wiring board. When effective use of resources is considered, it is not desirable to discard as defective such a wiring board having a disconnected portion of a conductive pattern. Thus, attempts have been made to repair the disconnected portion of a conductive pattern in a wiring board.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
an insulation layer; and
a conductive pattern formed on the insulation layer having a repaired disconnected portion,
wherein the repaired disconnected portion has a first conductive layer connecting disconnected edges of the conductive pattern and a second conductive layer covering the first conductive layer, the first conductive layer has a first electrical resistivity which is set higher than an electrical resistivity of the conductive pattern, and the second conductive layer has a second electrical resistivity which is set lower than the first electrical resistivity of the first conductive layer.

2. A wiring board according to claim 1, wherein the first conductive layer comprises a conductive-paste layer formed by drying and hardening a conductive paste including metal particles, and the second conductive layer comprises a plated layer comprising metal plating.

3. A wiring board according to claim 1, wherein the conductive-paste layer of the first conductive layer has a concave-convex surface, and the plated layer is formed on the concave-convex surface of the conductive-paste layer such that the metal plating of the plated layer is filling spaces of the concave-convex surface.

4. A wiring board according to claim 1, wherein the second conductive layer is formed on the first conductive layer such that the second conductive layer is extending between the disconnected edges of the conductive pattern.

5. A wiring board according to claim 4, wherein the conductive pattern is made of copper, and the second conductive layer is made of copper.

6. A wiring board according to claim 4, wherein the conductive pattern comprises copper, and the second conductive layer comprises copper.

7. A wiring board according to claim 1, wherein the second conductive layer has a thickness which is set in a range of 0.1 μm to 20 μm.

8. A wiring board according to claim 1, wherein the conductive pattern is made of copper, and the second conductive layer is made of copper.

9. A wiring board according to claim 1, wherein the conductive pattern comprises copper, and the second conductive layer comprises copper.

10. A wiring board according to claim 2, wherein the conductive-paste layer of the first conductive layer has a concave-convex surface, and the plated layer is formed on the concave-convex surface of the conductive-paste layer such that the metal plating of the plated layer is filling spaces of the concave-convex surface.

11. A method for manufacturing a wiring board, comprising:
applying a conductive paste including metal particles to a disconnected portion of a conductive pattern such that a layer of the conductive paste is formed between disconnected edges of the disconnected portion of the conductive pattern;
drying the layer of the conductive paste formed between the disconnected edges of the disconnected portion such that a conductive-paste layer having a first electrical resistivity which is set higher than an electrical resistivity of the conductive pattern is formed between the disconnected edges of the disconnected portion; and
electrolytically plating the conductive-paste layer using the conductive-paste layer as a power-supply layer such that a plated layer having a second electrical resistivity which is set lower than the first electrical resistivity of the conductive-paste layer is formed to cover the conductive paste layer.

12. A method for manufacturing a wiring board according to claim 11, wherein the conductive-paste layer is formed such that the metal particles agglomerate and form a concave-convex surface on the conductive-paste layer, and the plated-layer is formed such that plating of the plated-layer fills spaces of the concave-convex surfaces of the conductive-paste layer.

13. A method for manufacturing a wiring board according to claim 11, wherein the plated layer is formed on the conductive-paste layer such that the plated layer extends between the disconnected edges of the conductive pattern.

14. A method for manufacturing a wiring board according to claim 11, wherein the conductive pattern is made of copper, and the plating comprises electrolytically plating copper on the conductive-paste layer such that the plated layer made of copper is formed to cover the conductive-paste layer.

15. A method for manufacturing a wiring board according to claim 11, wherein the conductive pattern comprises copper, and the plating comprises electrolytically plating copper on the conductive-paste layer such that the plated layer comprising copper is formed to cover the conductive-paste layer.

16. A method for manufacturing a wiring board according to claim 11, wherein the plated layer is formed on the conductive-paste layer such that the plated layer has a thickness which is set in a range of 0.1 μm to 20 μm.

17. A method for manufacturing a wiring board according to claim 12, wherein the conductive pattern is made of copper, and the plating comprises electrolytically plating copper on the conductive-paste layer such that the plated layer made of copper is formed to cover the conductive-paste layer.

18. A method for manufacturing a wiring board according to claim 12, wherein the conductive pattern comprises copper, and the plating comprises electrolytically plating copper on the conductive-paste layer such that the plated layer comprising copper is formed to cover the conductive-paste layer.

19. A method for manufacturing a wiring board according to claim 13, wherein the conductive pattern is made of copper, and the plating comprises electrolytically plating copper on the conductive-paste layer such that the plated layer made of copper is formed to cover the conductive-paste layer.

20. A method for manufacturing a wiring board according to claim 13, wherein the conductive pattern comprises copper, and the plating comprises electrolytically plating copper on the conductive-paste layer such that the plated layer comprising copper is formed to cover the conductive-paste layer.
